(19) United States
(12) Patent Application Publication
(10) Pub. No.: US 2016/0178722 A1
(43) Pub. Date: Jun. 23, 2016

(54) METHOD FOR CHARACTERIZING MICROWAVE COMPONENTS

(71) Applicant: Fraunhofer-Gesellschaft zur Forderung der angewandten Forschung E.V., Munchen (DE)

(72) Inventor: Matthias Seelmann-Eggebert, Au (DE)

(73) Assignee: Fraunhofer-Gesellschaft zur Forderung der angewandten Forschung E.V., Munchen (DE)

(21) Appl. No.: 14/978,327

(22) Filed: Dec. 22, 2015

(30) Foreign Application Priority Data
Dec. 22, 2014 (DE) 102014119331.8

(51) Int. Cl. G01R 35/00; G01R 27/28

(52) U.S. Cl. CPC G01R 35/007; G01R 27/28

(57) ABSTRACT

A method for characterizing microwave components, particularly for calibrating network catalysts for the calibrated measurement of electronic microwave components, which method includes the following processing steps of (A) measuring the scattering coefficients of a number N of calibration standards, which number N of calibration standards is greater than necessary for an analytic determination of calibration parameters to be determined by way of calibration; (B) calculating the calibration parameters dependent on the measured scattering coefficients of the calibration standard. The calculation of the calibration parameters in the processing step B occurs based on an equation system as a function of predetermined S_{cal}-parameters of the calibration standard, and in a processing step C, after the processing step B, a quality criterion of the calibration parameters is determined.

### INCORPORATION BY REFERENCE

The following documents are incorporated herein by reference as if fully set forth: German Patent Application No. 102014119331.8, filed Dec. 22, 2014.

### BACKGROUND

The invention relates to a method for characterizing microwave components, particularly for calibrating network analyzers for the calibrated measurement of electronic microwave components.

In electronic microwave parts and/or components, such as millimeter-wave integrated circuits (MMICs) or microwave circuits, which are produced on a semiconductor disk, the so-called wafers, it is beneficial to electrically measure them after production. Here, a measurement can occur either after an optional division of the wafer, i.e. at individual components, however the measurement can also be performed prior to this division (on chip/on wafer-measurement).

The electric features of microwave components are described among other things by scattering coefficients (s-parameters). The scattering parameters include the transmission and reflection of the microwave components and the characterization of the small signal behavior, particularly the network behavior of the objects to be measured.

These scattering parameters may be determined via network analysis, for example as known from prior art, by performing a wafer measurement using network analyzers. Here the object to be measured, for example a microwave component, is excited at least at one of its inputs by a mono-frequency power wave coupled in at a coupling area, while the other connections (gates) are connected free from reflections by suitable loads. Here, the ratio of power output is measured (with regards to amount and phase), which is transported to the other gates and/or the portion reflected at the input of the object to be measured.

This measurement is performed at the entire system with the connection line and the test probes with the above-mentioned network analyzer and also comprises undesired couplings between the individual components.

Here it is however necessary, particularly in case of so-called vectorial network analysis, to perform a system error correction prior to the actual measurement of the electronic components in order to obtain precise measurements. For this purpose, prior to the measurement, a calibration of the network analyzer is performed based on so-called calibration standards, with here the electric parameters being known.

Calibration standards are known from prior art, which are arranged on a substrate. Alternatively, an in-situ calibration can also be performed, i.e. the calibration standards are arranged directly on the wafer, which comprises the objects to be measured. Common calibration methods are based on the standards “SHORT”, “OPEN”, “LOAD” as single-gate elements and transmission lines “THRU” and/or “LINE” with for example different lengths as two-gate elements.

Based on the knowledge of the electric parameters of the calibration standards, here so-called error terms may be determined as elements of a system-characterizing transformation matrix (calibration matrix). The error terms determined in this fashion are then considered as corrective data for the evaluation of data of the subsequent measurement of the electronic components to be measured.

In such configurations it is problematic, though, that particularly at higher frequencies, for example frequencies above 100 GHz, parasitic wave modes may spread over the open end of the transmission line in the calibration substrate. This effect leads to the circumstance that the signal actually measured during the calibration is not only based on the assumed calibration standard but includes additional signal components. This results in systematic measuring errors, which may represent substantial measuring errors, particularly in case of high frequencies. Due to the fact that the calibration data generally include no redundant information, though, the error developing is not discernible, either. Additionally, the error may even increase if the dielectric features of the substrate during calibration (typically ceramics) and during the measurement (typically a connection line, such as GaAs), are different.

Calibration methods are known from prior art, for example, which provide to measure the scattering coefficients of a plurality of calibration standards, which number of calibration standards is greater than required for an analytic determination of the calibration parameters that can be determined by way of calibration. For the calculation of the calibration parameters as a function of the measured scattering coefficients of the calibration standards, here ideal data is assumed with regards to the calibration standard.

However, it is disadvantageous in methods of prior art that neither the ideal data underlying the calibration methods with regards to said calibration standards nor the assumption of a serial circuit-topology are verified. This way, particularly in case of frequencies above 100 GHz, considerable systematic errors occur.

### SUMMARY

The present invention is therefore based on the objective to provide a method for characterizing microwave components, particularly for the calibration of network analyzers for the calibrated measurement of electronic microwave components, which allow a highly precise calibration of the microwave components.

This objective is attained in a method with one or more features of the invention. Preferred embodiments of the method according to the invention are provided below and in the claims. An application according to the invention is also disclosed. The wording of all claims is hereby explicitly included in the description by way of reference.

The method according to the invention for characterizing microwave components, particularly for the calibration of network analyzers for the calibrated measurement of electronic microwave components, includes the following processing steps:
A. Measuring the scattering coefficients of a number N of calibration standards, which number N of calibration standards is greater than necessary for an analytic determination of the calibration parameters that can be calibrated by way of calibration,
B. Calculating the calibration parameters as a function of the measured parameters of the calibration standards.

It is essential that the calculation of the calibration parameters in the processing step B occurs based on an equation system dependent on the predetermined S_{cal}-parameters of the calibration standards, and, after the processing step B, a quality criterion of the calibration parameters is determined in a processing step C.

The method according to the invention therefore differs in essential aspects from methods of prior art: The method according to the invention itself occurs based on known scattering coefficient of the calibration standards, comprehensively known for all frequency bands. Additionally, a determination of the quality criterion of the calibration parameters occurs, which allows a deduction regarding the quality of the calibration method.

This results in the particular advantages that a direct and unambiguous determination of the calibration parameters is possible, even in case of overdetermined systems, and the quality of the calibration method can be reviewed and evaluated subsequently via the quality factor, e.g., with regards to the consistency of the underlying calibration standards or the assumption of a serial circuit topology.

High requirements are set to the calibration standards: for example, their frequency-dependent small signal behavior must be known precisely and it must be possible to measure the calibration standards with a high degree of reproducibility. Further, they must provide a complete set of determination equations and allow an analytic solution of the conditional equation. Additionally, the calibration standards must be accessible in case of an on-wafer measurement even for the test probes, in a manner as simple as possible. The information required regarding the features of the calibration standard are known from manufacturers' information or they are preferably determined by way of measurements and/or simulation procedures.

In a preferred embodiment, in the processing step B, the calculation of the calibration parameters occurs without assuming any ideal condition with regards to the calibration standard. Accordingly, no ideal data is assumed with regards to the calibration standard as common in methods known from prior art. This way a substantial improvement of the precision of measurement results, particularly at frequencies above 100 GHz.

In another preferred embodiment the calculation of the calibration parameters occurs via an eight-term error model or a 16-term error mode. Here, the two-gate calibration models known from prior art, the above-mentioned eight-term error model and the above-mentioned 16-term error model.

In another preferred embodiment a first quality factor η_{K} is determined as the quality criterion, which allows a statement regarding the ability to calibrate the system. Preferably the first quality factor η_{K} is determined from the quotient of the smallest eigenvalue of the calibration matrix and the sum of the eigenvalues of the calibration matrix, thus according to the following formula:

$${η}_{K} = \frac{{λ}_{i}}{{\sum }_{n = 1}^{i} {λ}_{n}} \qquad ( 1 )$$

λᵢ represents the eigenvalues of the calibration matrix. When using the eight-term error model here eight eigenvalues develop, thus i=8. When using the 16-term error model sixteen eigenvalues develop, thus i=16.

If the quality factor exceeds a first threshold, preferably 10⁻⁶, in a preferred embodiment it is checked if an expansion of the eight-term error model to the 16-term error model may lead to a reduction of the first quality factor and thus to an improvement of the quality of the calibration method. Thus, based on the first quality factor it can be determined if the calculation of the calibration parameters can occur via a serial circuit typology. Preferably, in another step, when a first threshold for the first quality factor has been exceeded, the calculation of the calibration parameters occurs via a general network topology. This results in the advantage that by the subsequent evaluation of the quality of the calibration process via the first quality factor it can be decided if another expensive calibration step via the 16-error term model and a general network topology must occur. It is therefore ensured that conclusions are not permitted based on any insufficient calibration process.

In another preferred embodiment of the invention the calculation of the calibration parameter occurs via the serial circuit topology and the eight-term error model. Further, the first quality factor η_{K} is determined. If the first quality factor exceeds the first threshold, in a second iteration the calculation occurs of the calibration parameters using the general network topology and the 16-error term model. Subsequently, optionally the first quality factor is determined for a second time. This results in the advantage that after the first run of the calibration process it can be checked if a second calculation is necessary using more extensive calibration models.

In another preferred embodiment of the invention a second quality factor η_{E} is determined, which allows a conclusion regarding the unambiguousness of the calibration. Preferably the second quality factor η_{E} is determined from a quotient of the smallest eigenvalue of the calibration matrix and a sum of the smallest eigenvalue and the second-to-smallest eigenvalue of the calibration matrix, i.e. according to the following formula:

$${η}_{E} = \frac{{λ}_{i}}{{λ}_{i - 1} + {λ}_{i}} \qquad ( 2 )$$

λᵢ is the smallest eigenvalue of the calibration matrix and λᵢ₋₁ the second-to-smallest eigenvalue of the calibration matrix. Here, too, when using the eight-term error module eight eigenvalues (i=8) develop and when using the 16-term error module sixteen eigenvalues (i=16).

The second quality factor η_{E} also allows a subsequent evaluation of the quality of the calibration method. If the second quality factor η_{E} exceeds a second threshold, preferably 0.2, this is an indication for a high systematic error of the calibration. As a consequence, at least one degree of freedom of the calibration parameters remains undetermined. The systematic error of the calibration method is then so high that significantly false results are to be expected. The second quality factor η_{E} therefore represents a criterion for unambiguousness.

In another preferred embodiment in the processing step B the calculation occurs of the calibration parameters by minimizing the quadratic equation of the overdetermined equation system. Preferably the bilinear connection

γ(A,B,C,D)=S′ᵢBSᵢ+S′ᵢA−C−DSᵢ=0 (3)

is used as the equation system in the processing step B.

Here, S′ᵢ represent the scattering coefficients of the calibration standard and S_{cal,i} the predetermined S_{cal}-parameters of the calibration standards. A, B, C, and D are the unknown calibration matrices. These above-mentioned matrices respectively represent complex 2×2-matrices.

For a given frequency, each calibration standard provides a set of four conditional equations according to the formula (3) for the elements of the unknown calibration matrices. For the assumption of a general network topology here 16 unknown terms result. When assuming a serial circuit topology the four calibration matrices are diagonal and depend only on eight parameters.

In another preferred embodiment the calculation of the calibration parameters occurs in the processing step B by minimizing the expression.

F(A,B,C,D)=Σᵢ∥S′ᵢBSᵢ+S′ᵢA−C−DSᵢ∥²=Σᵢ∥Mᵢxₚ∥²=x′ₚWxₚ (4)

Here, xₚ represents a parameter vector of the calibration matrices. It includes the unknown matrix elements of the calibration matrices, Mᵢ is a matrix of all determination terms of the bilinear connection for the calibration standard i. The elements of the matrix Mᵢ forms the hermetic matrix W. Here it is not mandatory for a non-trivial solution of the expression that the determinant of the matrix W becomes zero. Preferably the equation system of the bilinear connection is attained via linear regression.

Preferably it applies for the matrix W of all determination terms of the bilinear connection:

det|W|=0 (5).

Here, the minimizing of the expression Wxₚ occurs preferably via linear regression as well as an eigenvalue disintegration. By a transformation of the matrix Mᵢ a diagonal eigenmatrix W develops with the eigenvalue xₚ. The solution to be determined for the calibration parameters includes any multiple of the eigenvector of the diagonal eigenmatrix W.

In another preferred embodiment the measuring of the scattering coefficients of the calibration standard occurs in the processing step A as an on-wafer measurement. On-wafer measurements for the determination of the scattering coefficients are known from prior art. For this purpose, the calibration standards are applied at least at the input by a mono-frequency power wave, while the other connections (gates) are connected free from reflection by suitable loads, causing the ratio of the output being measured (with regards to amount and phase), which is transmitted to the other gates and/or the portion reflected at the input of the object to be measured.

Preferably the measurement of the scattering coefficients of the calibration standards occurs in the processing step A in a frequency range above 110 GHz. In particular in a frequency range above 110 GHz, parasitic wave modes can spread via open ends of the transmission lines over the calibration standard, for example in the substrate. The influences caused by such parasitic wave modes are largely dependent on the environment of the calibration standard and may lead to substantial measuring errors. These substantial measuring errors may be significantly reduced by the use of the calibration method according to the invention.

Preferably, the calibration method is performed via an arrangement for calibrating a network analyzer for the calibrated measurement of electronic components, as described in the German patent application DE 10 2012 205 943 A1. This patent application is incorporated completely herein by reference as if fully set forth. Such an arrangement includes a plurality of calibration standards, arranged on a carrier and embodied as a microwave component, for calibrating a network analyzer. The calibration standards respectively show at least one coupling area with at least one coupling point for coupling a wave. Here, the coupling area has a shield, which shield completely surrounds the interior conductor of the calibration standard with all coupling points, at least in the plane in which the calibration standard extends. The coupling point is therefore shielded at least in the above-mentioned plane and at least at the side facing away from the calibration standard from exterior influences and/or any interaction with elements outside the shielded area is avoided or at least reduced. Based on the shielding any error sources generated by parasitic wave modes are neutralized or at least considerably reduced in their influence. This way the precision of the calibration method can be significantly increased. The use of this preferred arrangement for calibration in the method according to the invention or a preferred embodiment of the method according to the invention allows therefore a highly precise calibration, particularly at frequencies above 110 GHz, and simultaneously allows a determination of the quality of the calibration with regards to solvability and unambiguity. Particularly at these high frequencies, here a considerable improvement of the calibration method and thus the measuring results can be yielded.

The method according to the invention is generally suitable for applications in which microwave components, particularly network catalysts are calibrated based on calibration standards. The method according to the invention is preferably embodied for the use within the scope of a measurement of a number of calibration standards, which is greater than the number of the calibration standards possible for an analytic determination. Here, the method offers the advantage of a universal application as well as the fact that no ideal values need to be assumed with regards to the calibration standards.

1. A method for characterizing microwave components, the method comprises the following processing steps:
A measuring scattering coefficients of a number N of calibration standards, said number N of calibration standards is greater than necessary for an analytic determination of calibration parameters that are being determined by the calibration;
B calculating the calibration parameters as a function of scattering coefficients of the calibration standards measured, wherein the calculation of the calibration parameters in the processing step B occurs based on an equation system depending on predetermined S_{cal}-parameters of the calibration standards, and
C after the processing step B, determining a quality criterion of the calibration parameters.

2. The method according to claim 1, wherein
in the processing step B the calculation of the calibration parameters occurs without assuming any ideal values with regards to the calibration standard.

3. The method according to claim 1, wherein
the calculation of the calibration parameters occurs via an 8-term error model, a 16-term error model, or both.

4. The method according to claim 1, wherein
a first quality factor is determined as the quality criterion that allows a conclusion regarding an ability to calibrate the system.

5. The method according to claim 4, wherein
the first quality factor is determined from a quotient of a smallest eigenvalue and a sum of eigenvalues.

6. The method according to claim 5, further comprising
based on the first quality factor, determining if the calculation of the calibration parameters can occur via a serial circuit topology.

7. The method according to claim 6, further comprising
upon a first threshold for the first quality factor being exceeded, performing the calculation of the calibration parameters via a general network topology.

8. The method according claim 4, further comprising
Determining a second quality factor that allows a conclusion regarding an unambiguity of the calibration.

9. The method according to claim 8, wherein
the second quality factor is determined from a quotient of a smallest eigenvalue and a sum of a smallest eigenvalue and a second-to-smallest eigenvalue.

10. The method according to claim 1, further comprising in the processing step B, performing the calculation of the calibration parameters by minimizing a quadratic deviation of an overdetermined equation system.

11. The method according to claim 1, further comprising
in the processing step B, using a bilinear connection
γ(A,B,C,D)=S′ᵢBSᵢ+S′ᵢA−C−DSᵢ=0
as the equation system, with S′ᵢ representing measured scattering coefficients of the calibration standards and S_{cal,i} representing predetermined S_{cal}-parameters of the calibration standards, and A, B, C, and D representing calibration matrices.

12. The method according to claim 1, further comprising
performing the calculation of the calibration parameters in the processing step B by minimizing an expression
F(A,B,C,D)=Σᵢ∥S′ᵢBSᵢ+S′ᵢA−C−DSᵢ∥²=Σᵢ∥Mᵢxₚ∥²=x′ₚWxₚ
with xₚ representing a parameter vector of calibration matrices and Mᵢ representing a matrix of all determination terms of bilinear connections for a calibration standard i, with elements forming a Hermitian matrix W.

13. The method according to claim 12, wherein minimizing of the expression Wxₚ occurs via linear regression and a disintegration of the eigenvalue.

14. The method according to claim 12, further comprising
for the matrix W of all determination terms of the bilinear connection,
det|W|=0.

15. The method according to claim 1, wherein
measuring the scattering coefficients of the calibration standards in the processing step A occurs as an on-wafer measurement in a frequency range above 110 GHz.

16. The method according to claim 1, further comprising
performing the calibration method via an arrangement for calibrating a network analyzer for calibrated measurement of electronic components, said arrangement comprising a plurality of calibration standards, arranged on a carrier and embodied as microwave components, for calibrating a network catalyst, with an coupling area having a shielding that surrounds at least the coupling area of the calibration standard at least in a plane in which the calibration standard extends.

17. The method according to claim 1, wherein the method is for calibration of network analyzers for the calibrated measurement of electronic microwave components.
